(19) United States
(12) Patent Application Publication
(10) Pub. No.: US 2024/0222221 A1
(43) Pub. Date: Jul. 4, 2024

(54) MIXED PHASE THERMAL INTERFACE MATERIAL ASSEMBLY WITH HIGH THERMAL CONDUCTIVITY AND LOW INTERNAL CONTACT RESISTANCE

(71) Applicant: NVIDIA Corporation, Santa Clara, CA (US)

(72) Inventors: Padam Jain, Santa Clara, CA (US); Ronilo Boja, Santa Clara, CA (US)

(21) Appl. No.: 18/149,617

(22) Filed: Jan. 3, 2023

(51) Int. Cl. H01L 23/427; H01L 21/48; H01L 23/433

(52) U.S. Cl. CPC H01L 23/427; H01L 21/4882; H01L 23/433; H01L 24/16

(57) ABSTRACT

An IC package including an IC and a TIM assembly located on the IC. The TIM assembly includes a lid defining a compartment, a mixed-phase material located in the compartment, the mixed-phase material including nanostructures, and a liquid metal occupying open spaces in the compartment that are not occupied by the nanostructures. A method of manufacturing an IC package, including providing the IC and placing the TIM assembly on the IC. A computer having one or more circuits that include the IC package.

### TECHNICAL FIELD

This application is directed, in general, to integrated circuit (IC) operations, and in particular, an IC package including a mixed phase thermal interface material (TIM) assembly for dissipating heat from a microprocessor chip of the IC package, and, methods of manufacturing an IC package including the TIM assembly.

### BACKGROUND

As chips (e.g., microprocessor chips or dies such as central processing unit chips, CPUs or graphical processing unit chips, GPUs) decrease in size and increase in performance, facilitating the dissipation of heat from the microprocessor using TIMs is of increasing importance to further higher performance and miniaturization. Arrays of micro- or nano-wires, tubes, pillars or posts (generally referred to as nanostructures herein) made of materials of high thermal conductivity have been proposed as a TIM. Often, to impart mechanical stability to the nanostructure a polymer matrix is infiltrated between the individual nanostructures. Liquid metals have been proposed as TIMs.

### SUMMARY

One aspect provides an IC package including an IC and a TIM assembly located on the IC. The TIM assembly includes a lid defining a compartment, a mixed-phase material located in the compartment, the mixed-phase material including nanostructures, and a liquid metal occupying open spaces in the compartment that are not occupied by the nanostructures.

Another aspect provides a method of manufacturing an IC package, including providing the IC and placing the TIM assembly on the IC.

### BRIEF DESCRIPTION

Reference is now made to the following descriptions taken in conjunction with the accompanying drawings, in which:

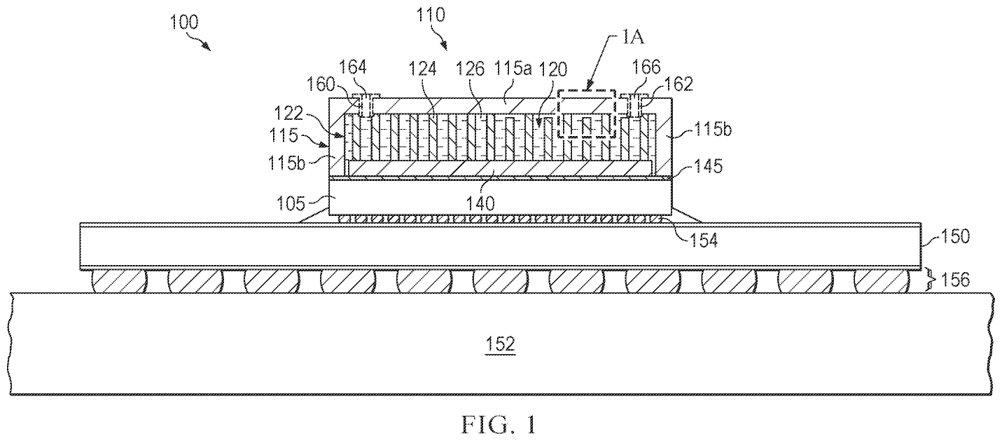

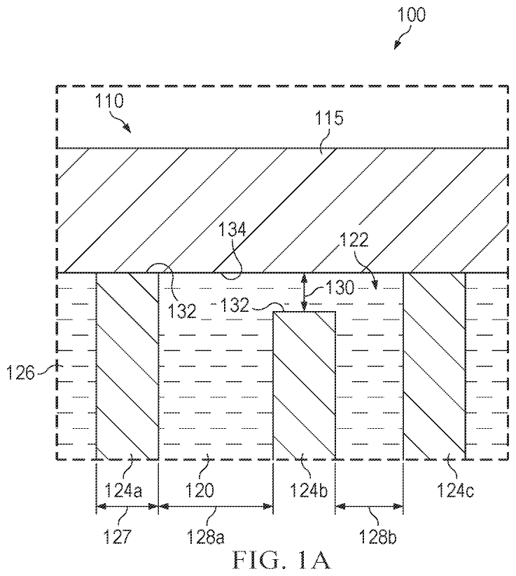

FIG. 1 presents a cross-sectional view of an example embodiment of an IC package, including an example embodiment of the TIM assembly of the disclosure;

FIG. 1A presents a detail view of a portion of the IC package depicted in FIG. 1;

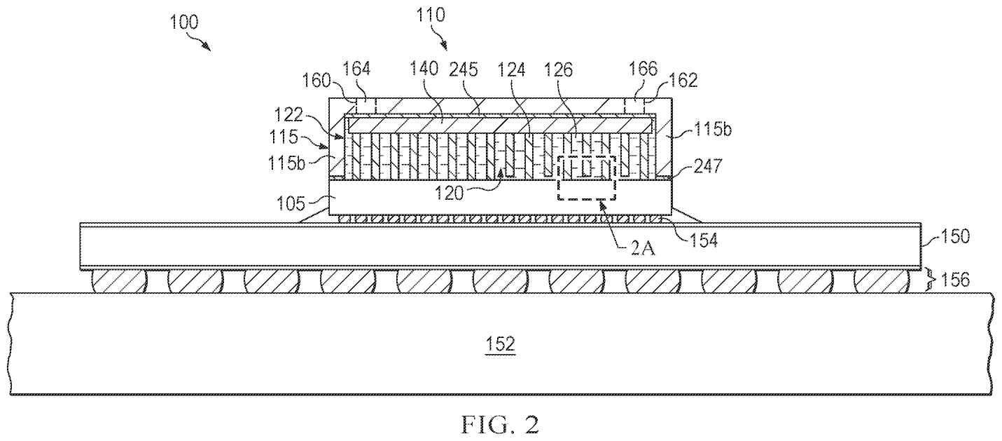

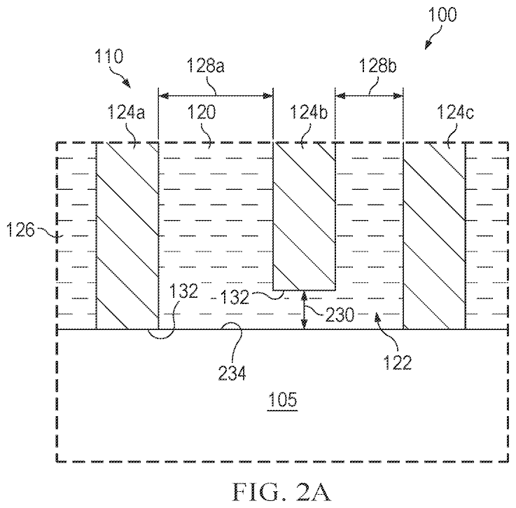

FIG. 2 presents a cross-sectional view of another example embodiment of the IC circuit package, including another example embodiment of the TIM assembly of the disclosure;

FIG. 2A presents a detail view of a portion of the IC package depicted in FIG. 2;

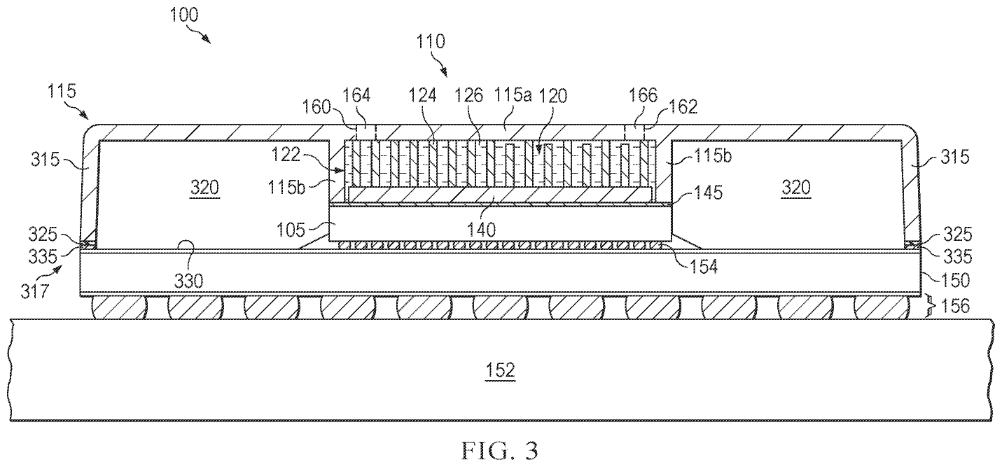

FIG. 3 presents a cross-sectional view of another example embodiment of the IC circuit package, including another example embodiment of the TIM assembly of the disclosure;

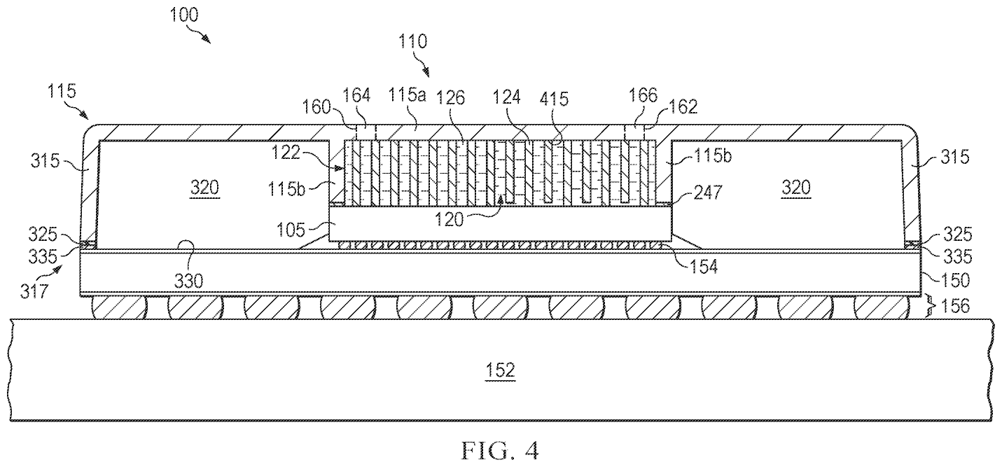

FIG. 4 presents a cross-sectional view of another example embodiment of the IC circuit package, including another example embodiment of the TIM assembly of the disclosure;

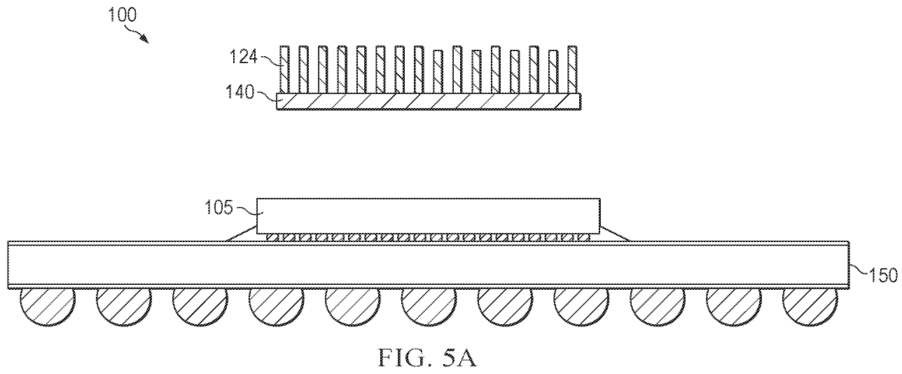

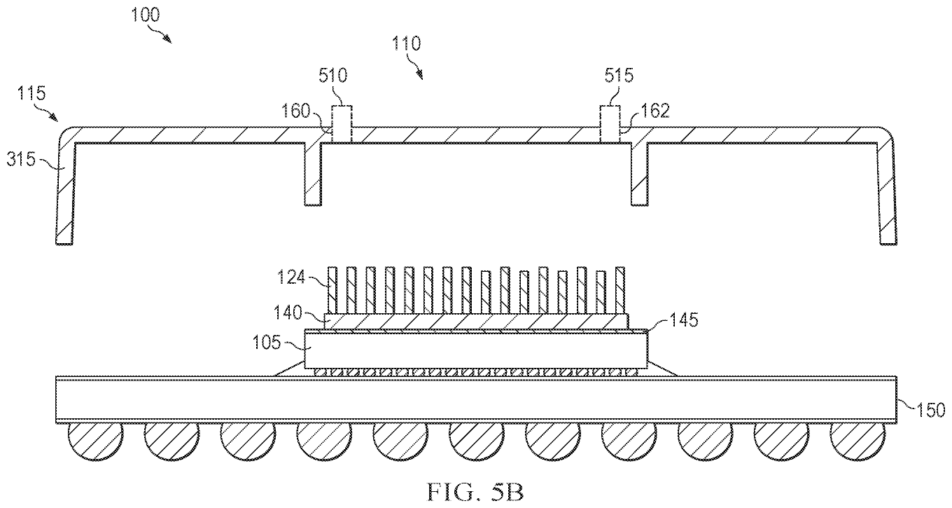

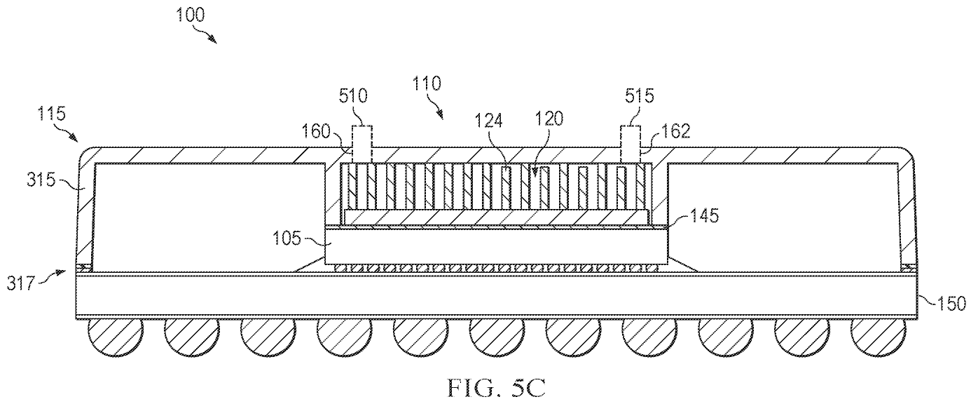

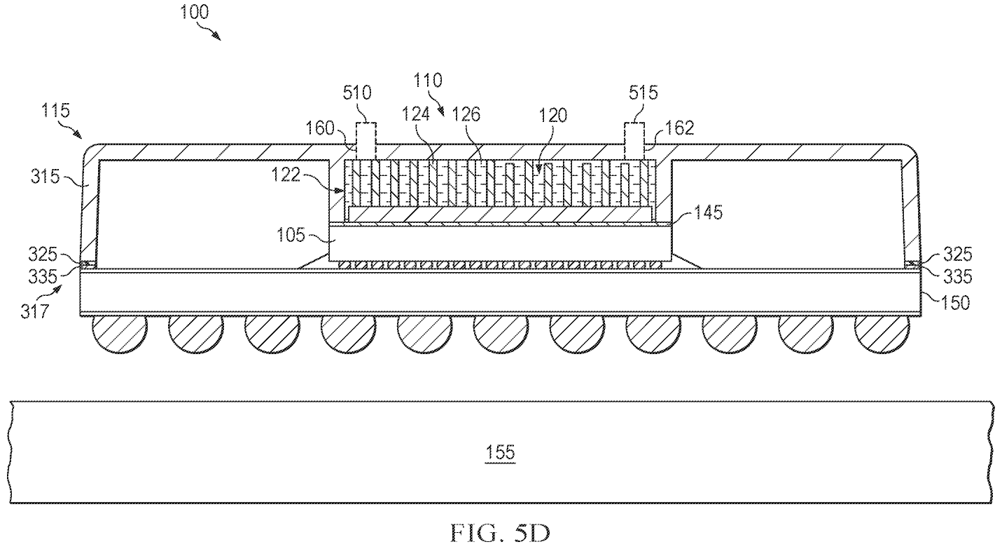

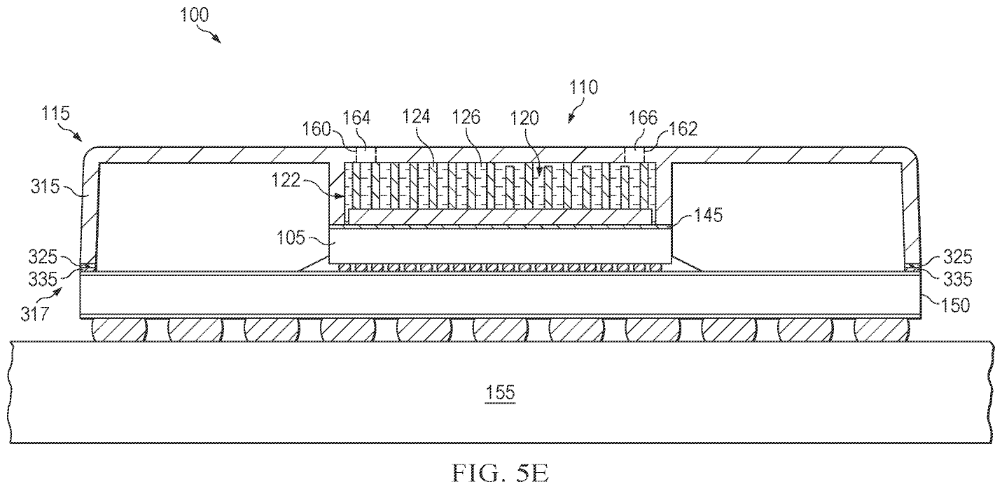

FIGS. 5A-5E presents cross-sectional views of an example IC package, such as any of the example embodiments disclosed in the context of FIGS. 1 and 3, at different stages of manufacture;

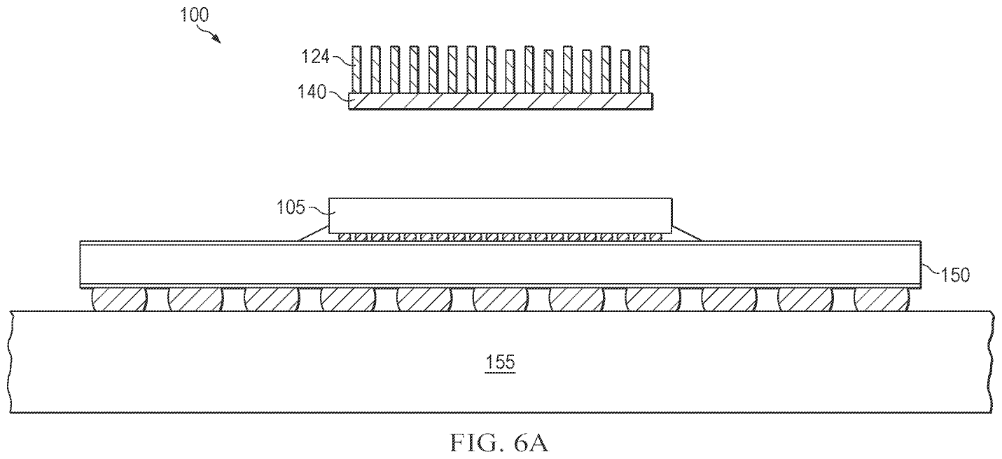

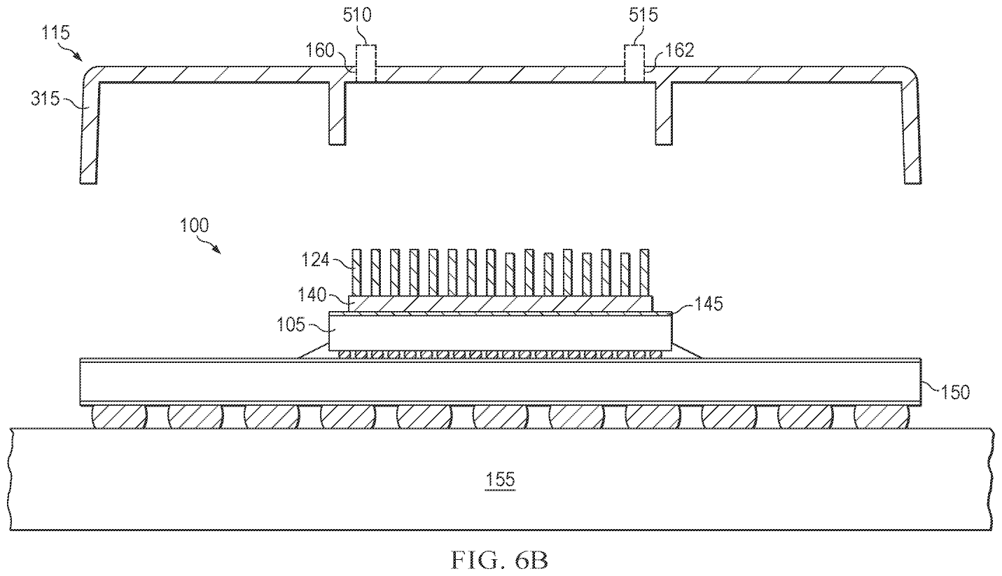

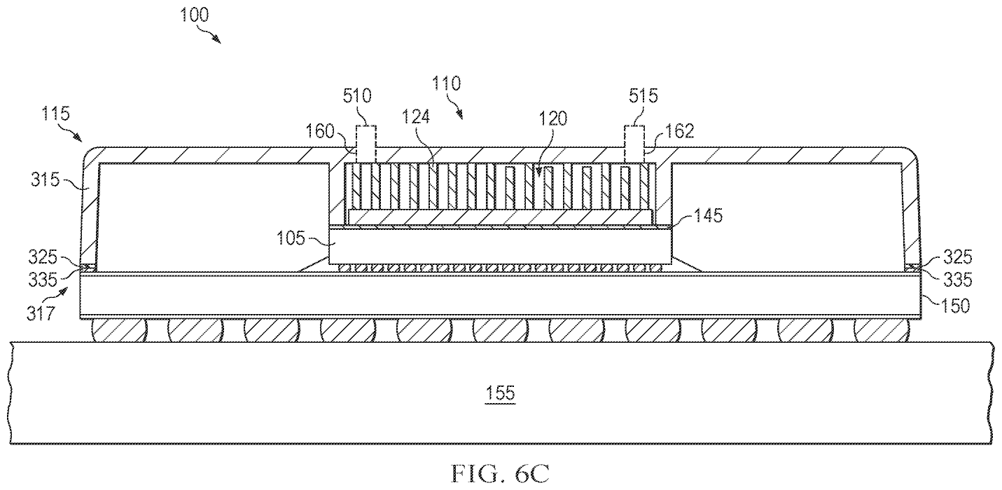

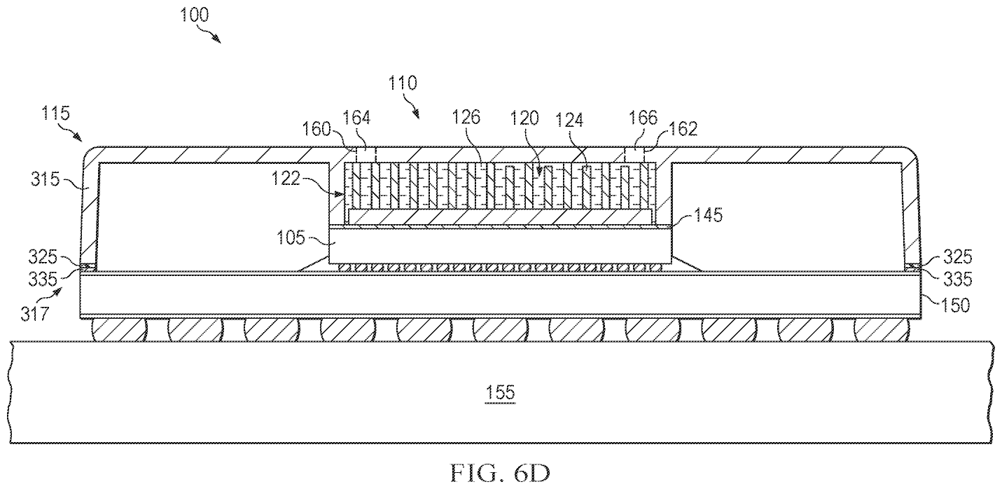

FIGS. 6A-6D presents cross-sectional views of an example IC package, such as any of the example embodiments disclosed in the context of FIGS. 1 and 3, at different stages of manufacture;

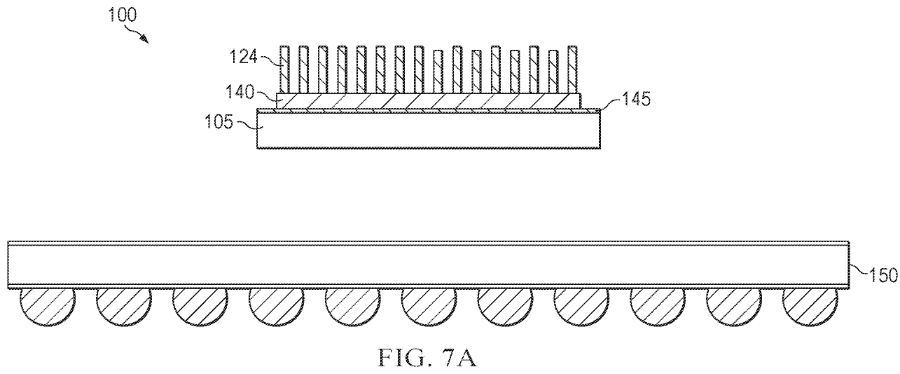

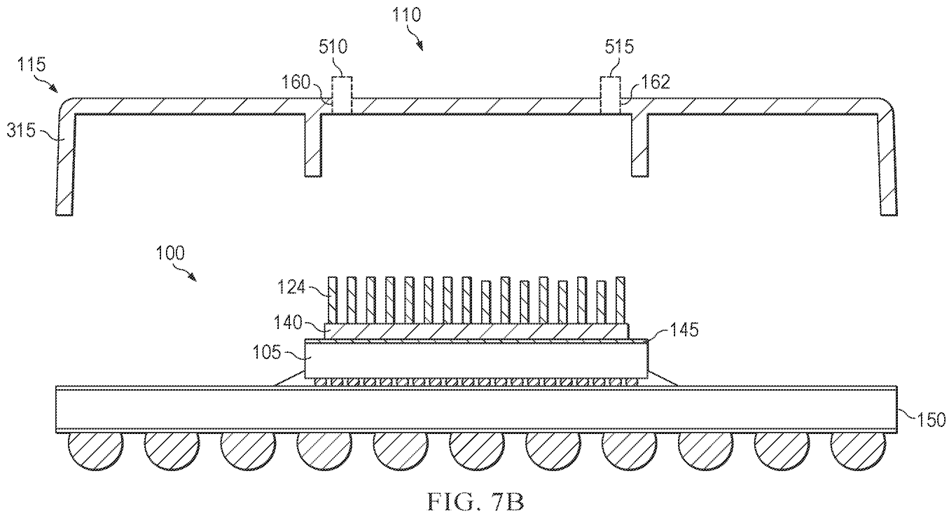

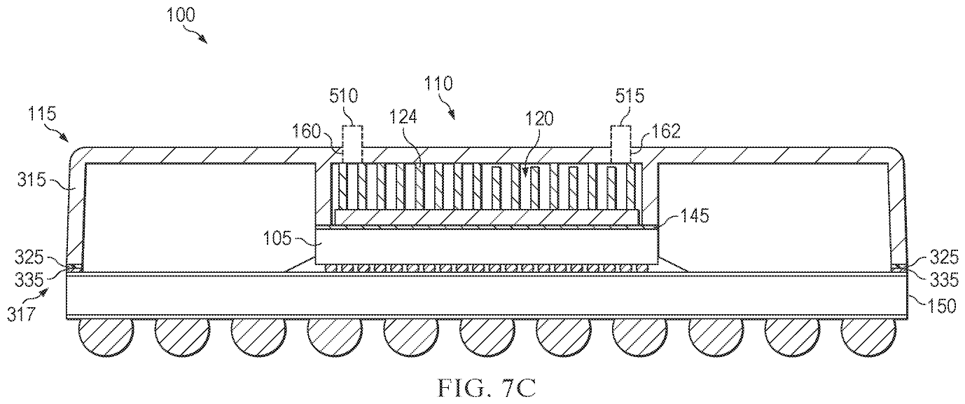

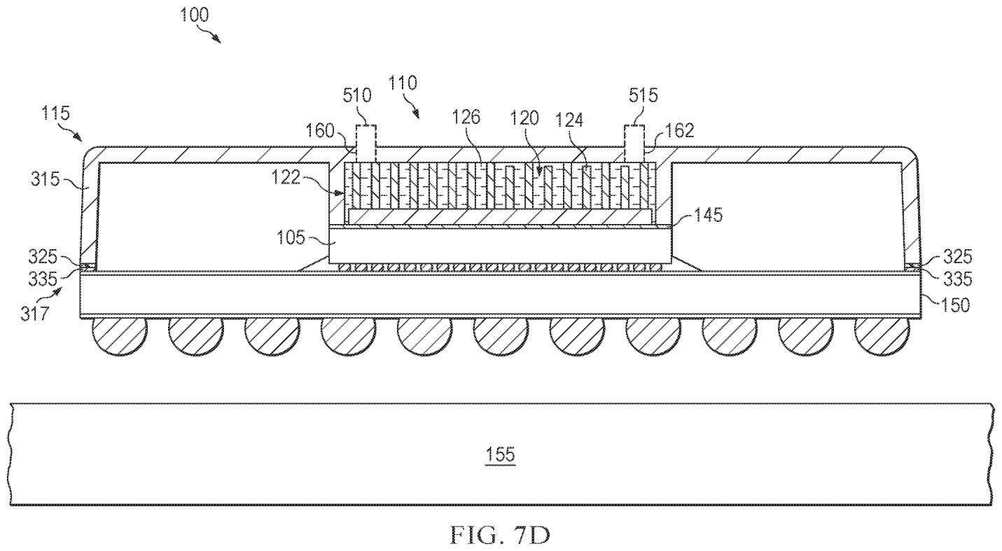

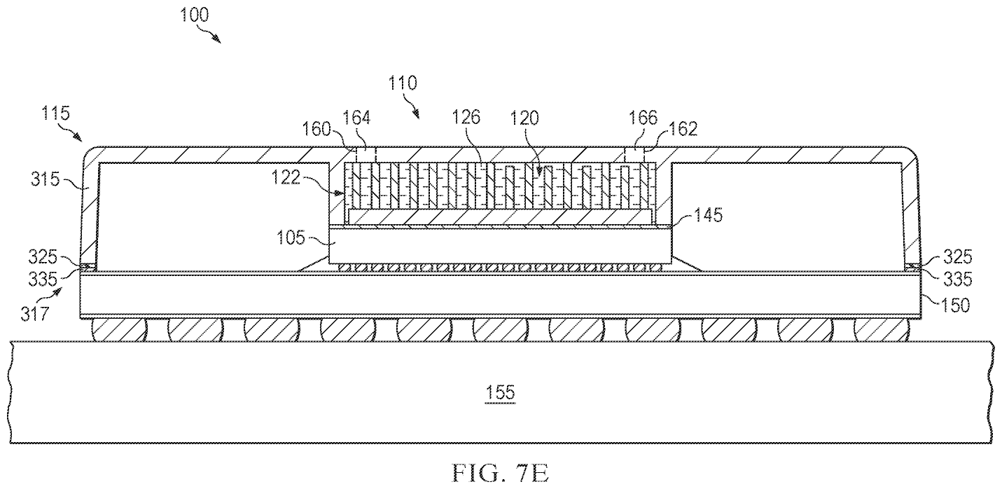

FIGS. 7A-7E presents cross-sectional views of an example IC package, such as any of the example embodiments disclosed in the context of FIGS. 1 and 3, at different stages of manufacture;

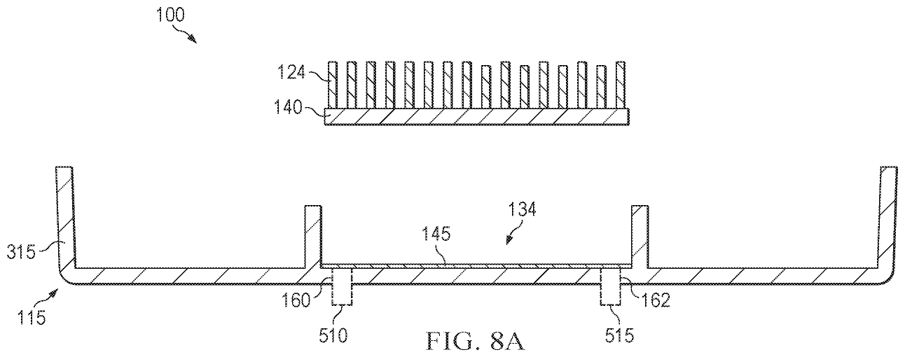

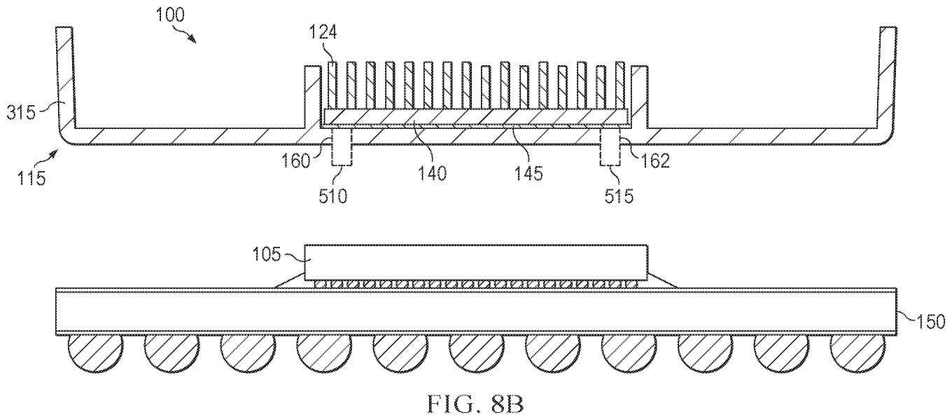

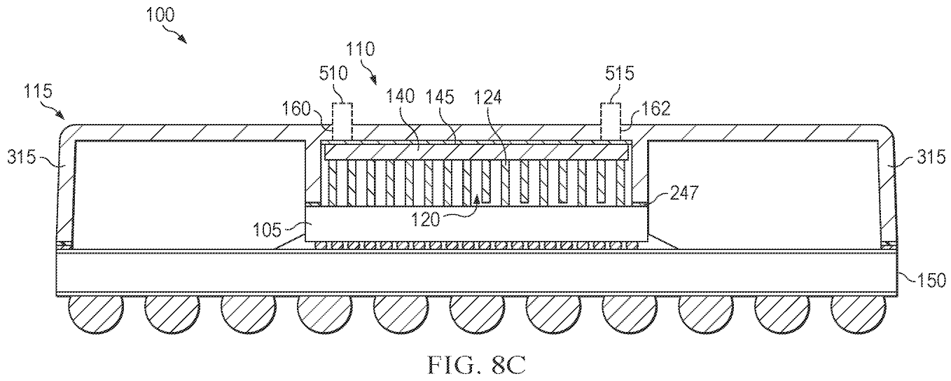

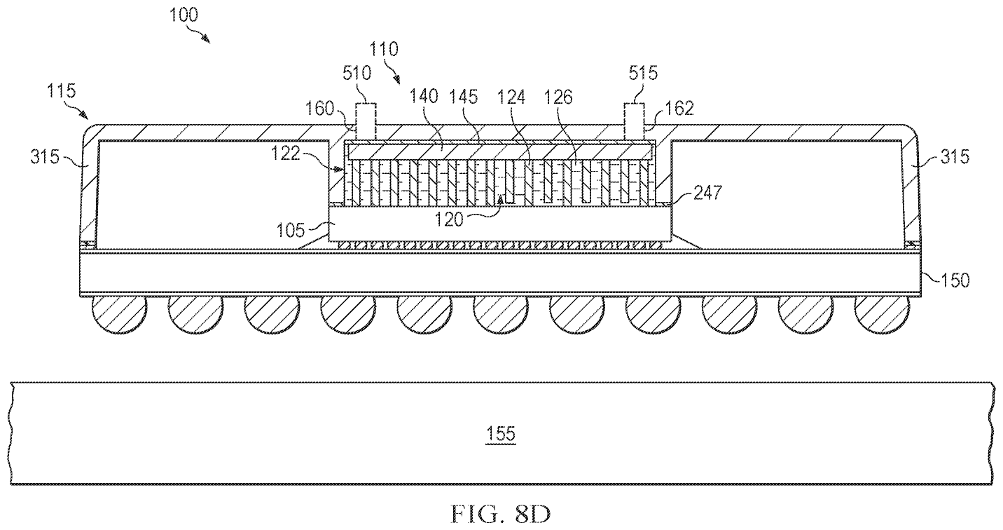

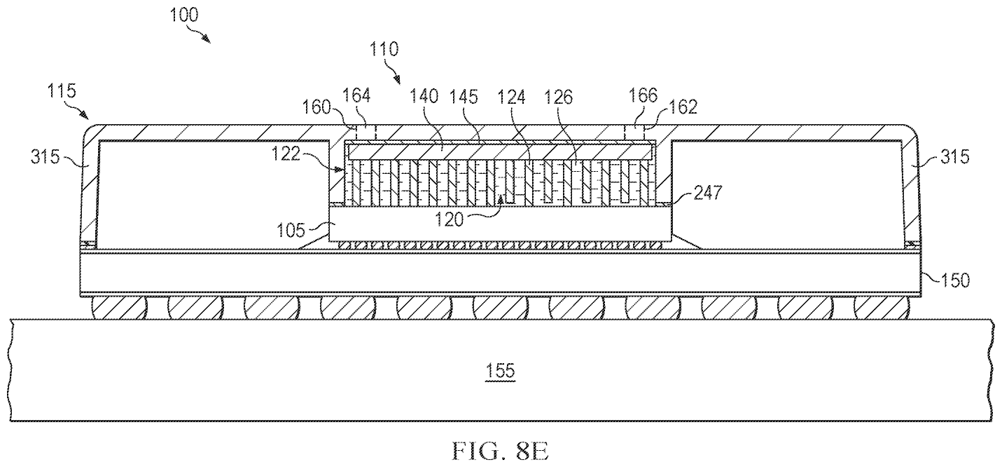

FIGS. 8A-8E presents cross-sectional views of an example IC package, such as any of the example embodiments disclosed in the context of FIG. 2, at different stages of manufacture;

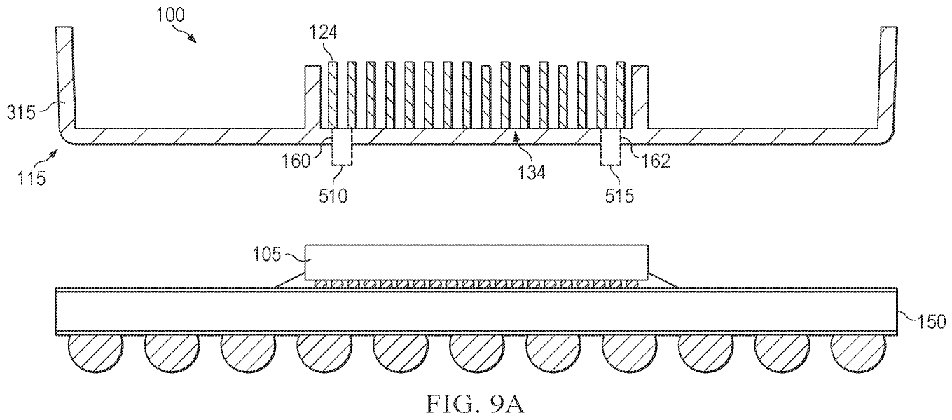

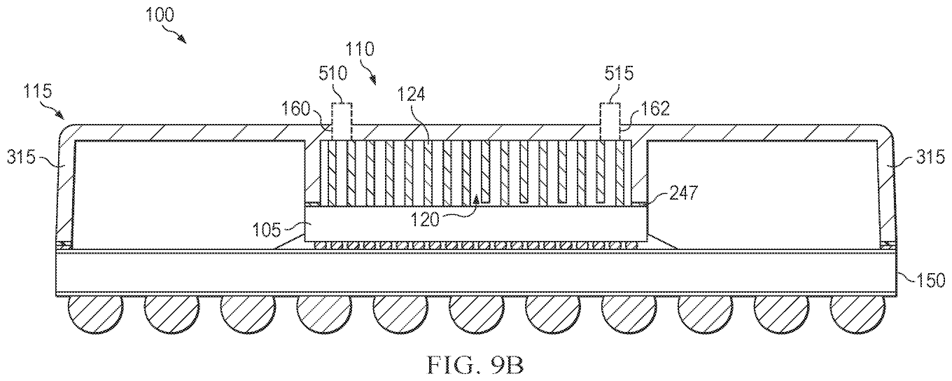

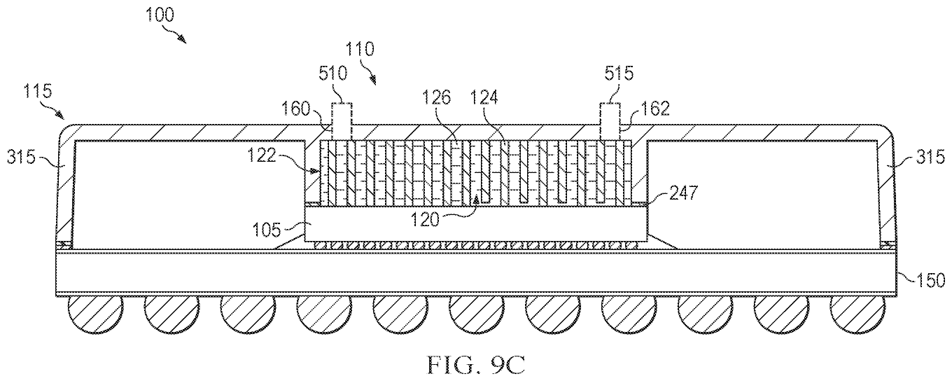

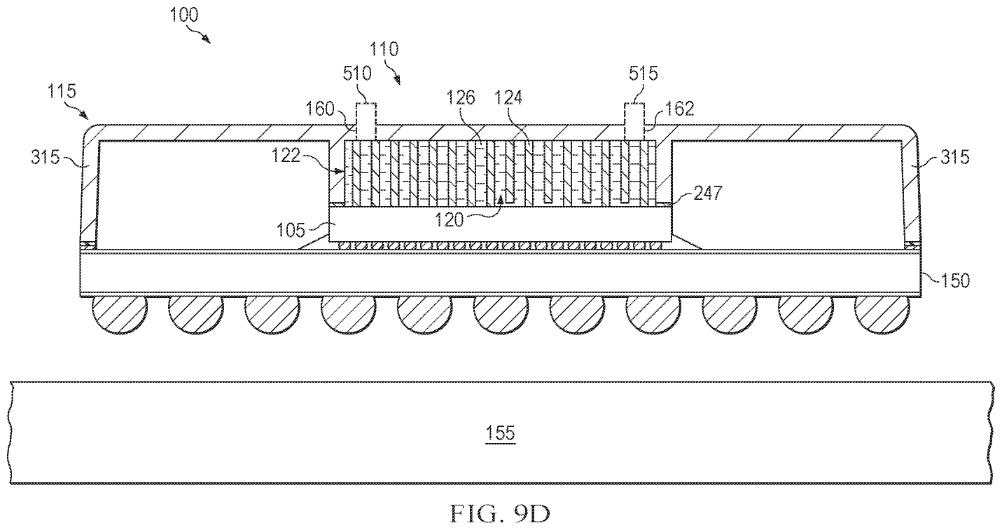

FIGS. 9A-9E presents cross-sectional views of an example IC package, such as any of the example embodiments disclosed in the context of FIG. 4, at different stages of manufacture;

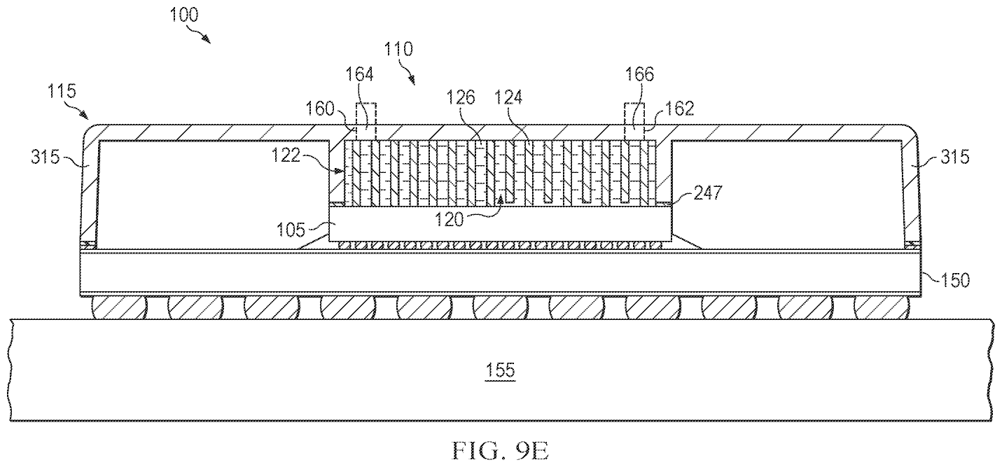

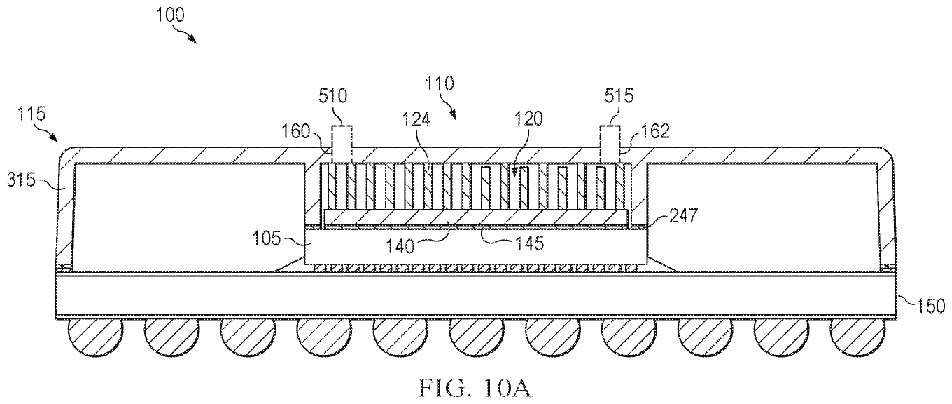

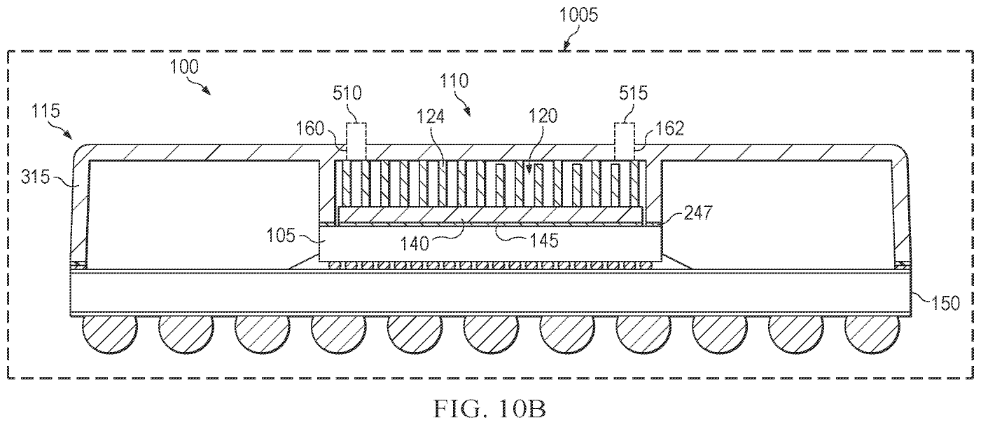

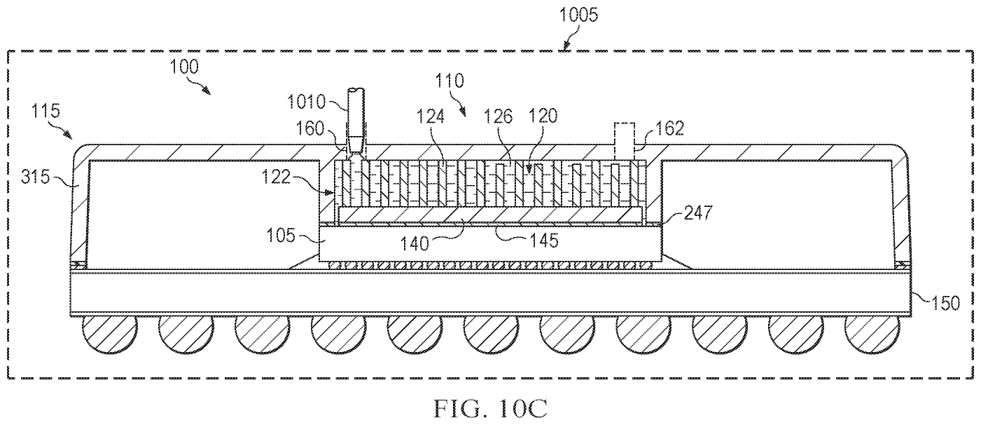

FIGS. 10A-10D presents cross-sectional views of an example IC package, such as any of the example embodiments disclosed in the context of FIGS. 1-4, at different stages of manufacture including filling a compartment of the TIM assembly with a liquid metal; and

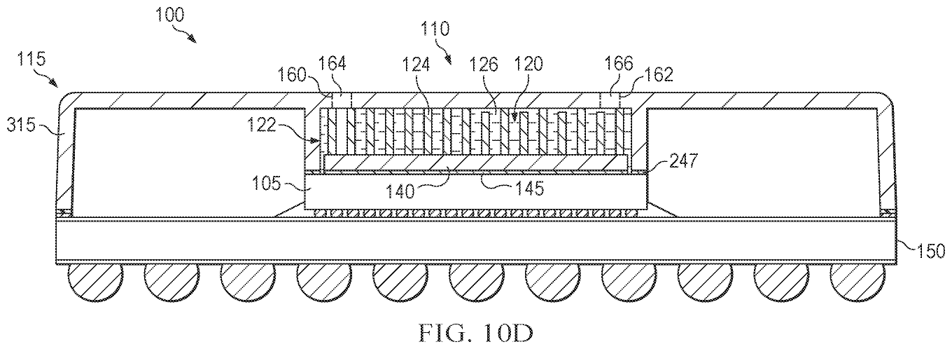

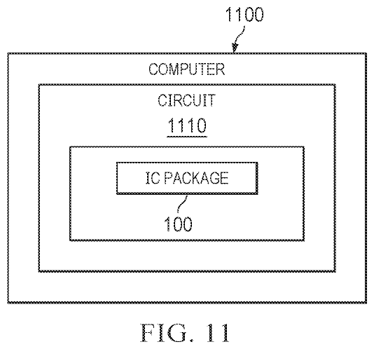

FIG. 11 presents a block diagram of a computer including one or more embodiments of the IC package such as disclosed in the context of FIGS. 1-10D.

### DETAILED DESCRIPTION

Embodiments of the disclosure follow from our study of certain deficits associated with TIMs composed of nanostructures infiltrated with a polymer material or with TIMs composed of liquid metals only.

While metal or carbon nanostructures have a high thermal conductivity, typically their thermal conductivity is only along one direction, e.g., along a long axis of the nanostructures. Moreover, to transfer heat by lowering thermal contact resistance, ideally, each of the nanostructures physically contacts a heat-absorbing structure to which heat is to be transferred to (e.g., a heat sink or heat spreader layer). Because the nanostructures may not all be the same height, to facilitate physical contact, the nanostructure may be ground (e.g., mechanical grinding or chemical mechanical polishing) and/or a mechanical load may be placed on the nanostructures. E.g., a heat sink layer or other thermal transfer interface layer may be pressed onto the nanostructure so that a greater number of more complete physical contact with the nanostructures is made. However, such grinding or mechanical loading can damage, e.g., break or buckle, at least some of the nanostructures, which in turn, decreases the broken or buckled nanostructure's thermal conduction to a heat sink, and thereby reducing heat transfer.

To help mitigate such damage, the nanostructures are structurally supported, e.g., by infiltrating the spaces between the nanostructures with a polymer matrix. Since polymer matrix compositions (e.g., polysilicones, such as polydimethylsiloxane, PDMS or epoxy resins) typically have low heat conductivity (e.g., 0.1 to 0.5 W/mK) they form a thermal insulation layer around the nanostructures, thereby decreasing heat transfer. Some of the polymer matrix can get in-between the tops of nanostructures and an overlying heat absorbing structure and thereby increase thermal contact resistance. To avoid having polymer between the tops of the nanostructures and the overlying heat absorbing structure, even great mechanical loading is applied to ensure direct contact between the nanostructures and heat sink, but, this increases the damage to the nanostructures.

TIMs composed of liquid metals only, such as Gallium and Gallium-based alloys (e.g., Ga in combination with one or more of In, Zn, or Sn), while having a low thermal contact resistance, do not have as high a level of thermal conductivity (e.g., 15 to 28 W/mK) as solid metals such as aluminum, copper gold or silver (e.g., 200 to 300 W/mK) and the liquid metal's electrical conductivity creates a risk of introducing short circuits in the IC. Liquid metals have been incorporated into a polymer matrix to form solid or semi-solid less electrically-conductive foams or pastes, but, such structures have reduced thermal conductivity as compared to a pure or neat liquid metal.

As part of the present invention, we realized that a mixed phase of liquid metal and solid nanostructures can take advantage of the different beneficial thermal properties of these materials to form a new mixed phase composite TIM assembly. As further disclosed herein, the beneficial high thermal conductivity of carbon or metal nanostructures can be combined with the beneficial low thermal contact resistance of liquid metal by combining and containing the nanostructures and liquid metal together in a compartment created by a lid structure that is situated over a heat generating chip. The liquid metal surrounding the nanostructures inside the compartment lowers the thermal contact resistance between the nanostructures themselves and between the nanostructures and the lid. Consequently, no, or less, grinding or mechanical loading on the nanostructures is required, thereby mitigating this source of damage to the nanostructure. We also realized that, because the nanostructures are not damaged, or less prone to being damaged by grinding or mechanical loading, a polymer matrix to mechanically stabilize the nanostructures, was not needed. That is, the compartment, within which the nanostructures and liquid metal are located, can be free of any polymer matrix material, thereby improving the overall thermal conductivity our TIM assembly.

One aspect of the disclosure is an IC package. FIGS. 1-4 present various embodiments of example IC packages 100 of the disclosure.

As illustrated in FIG. 1 embodiments of the IC package 100 includes an IC 105 and a TIM assembly 110 located on the IC 105. The TIM assembly can include a lid 115 (e.g., a Cu lid) defining a compartment 120, and a mixed-phase material 122 located in the compartment 120. The mixed-phase material includes nanostructures 124 and a liquid metal 126 occupying open spaces in the compartment that are not occupied by the nanostructures.

The term nanostructure as used herein refers to a metal (e.g., copper) or carbon (e.g., carbon nanotube) structures having at least one dimension (e.g., FIG. 1A, dimension 127) of less than one millimeter and in some embodiments of less than one micrometer. Non-limiting examples of such structures include wires, tubes, pillars or posts whose diameter is less than one millimeter, and in some embodiments, less than one micrometer. A plurality of such nanostructure can be formed on a surface (e.g., on the IC or on an interior lid surface) as one or more regular or irregular arrays of spaced apart nanostructures.

As illustrated in FIG. 1A, in some embodiments of the IC package 100, the open spaces occupied by the liquid metal includes gaps between adjacent ones of the nanostructures (e.g., gap 128a between nanostructures 124a and 124b; gap 128b between nanostructures 124b and 124c). As non-limiting examples, in some embodiments, a regular or irregular array of the nanostructures can have an average gap that is a value in a range from 1 to 1000 microns (e.g., 1, 10, 50, 100, 150, 200, 250, 300, 400, 500, 700, 1000 microns+10%).

Additionally, as further illustrated in FIG. 1A, in some embodiments, the open spaces include gaps 130 between tops 132 of some of the nanostructures (e.g., nanostructure 124b) and an interior surface 134 of the lid (e.g., a lid ceiling 115a facing the IC 105). As non-limiting examples, in some embodiments, a regular or irregular array of the nanostructures can have an average gap 130 that is a value in a range from 0 to 1000 microns (e.g., less than 0.1, 1, microns or 1, 10, 50, 100, 150, 200, 250, 300, 400, 500, 700, 1000 microns+10%). In some such embodiments, tops 132 of some of the nanostructures (e.g., nanostructures 124a, 124c) contact the interior surface 134 of the lid (e.g., the gap 130 is 0 microns). As non-limiting examples, in some embodiments, at least 50, 60, 70, 80, 90, 95, 99 or 99.9 percent of the nanostructure tops 132 contact the lid (e.g., lid ceiling 115a).

In any embodiments of the IC package 100, the liquid metal can occupy 50, 70, 90, 99, 99.9 percent of the open space (e.g., occupying gaps 128a, 128b, 130) in the compartment 120 that are not occupied by the nanostructures.

As further illustrated in FIG. 1, for some embodiments, the TIM assembly 110 can include a nanostructure seed growth layer 140 (e.g., an In, Ag or Cu foil), where the nanostructures 124 are connected to the nanostructure seed growth layer 140 and the nanostructure seed growth layer is on the integrated circuit 105. In some such embodiments, the TIM assembly 110 can further include a metal coupling layer 145 that holds the lid 115 and nanostructure seed growth layer 140 on the IC 105. For some such embodiments, the nanostructure seed growth layer 140 and lid walls 115b can be bonded to different segments of a same one of the metal coupling layer 145 to thereby hold the lid and the nanostructure seed growth layer in place on the IC. However, for other such embodiments, the nanostructure seed growth layer 140 and lid walls 115b can be bonded to different ones of metal coupling layers.

Non-limiting examples of the metal coupling layer 145 include solder materials such as indium or indium based alloys that can be directly soldered to a metallized silicon IC, or gallium based liquid metals where the surface tension of the liquid metal can prevent the overflow of the liquid metal layer or a dam structure around the silicon IC can also be used to prevent spill-over of the liquid metal.

In any such embodiments, the metal coupling layer 145 can form a liquid-tight seal between the lid 115 and the IC 105. That is, the metal coupling layer 145 can prevent the liquid metal 126 from exiting the compartment 120, e.g., to help prevent the liquid metal shorting out other electrical components of the PCB 155 or computer that the IC package 100 is located in, and, and prevent the entrance of external liquids (e.g., environmental water including water vapor or other liquids used as part of the package's fabrication) from entering the compartment and damaging the IC 105 or nanostructures 124.

As further illustrated in FIG. 1, in any embodiments, the IC 105 can be connected to a package substrate 150 of the IC package 100 and the package substrate can be connected to a printed circuit board (PCB) 152 of the IC package 100. For instance, one or more chips of the IC can be connected to the package substrate 150 via a solder ball array 154 and the package substrate 150 can be connected to the PCB 152 via a second solder ball array 156.

As further illustrated in FIG. 1, in any embodiments, the lid 115 can further include ports (e.g., fill port 160, vent port 162) with closures (e.g., fill closure 164, vent closure 166) to seal the liquid metal 126 in the compartment 120 (e.g., a liquid-tight seal). Non-limiting examples of suitable closures include rubber sealing plugs, e.g., with a head that rests on the outside of the lid 115 and internal lip that rests on the inside of the lid and inside the compartment 120 and/or metal sealing screws e.g., with captive O-rings surrounding the head of the screw that rests on the outside of the lid 115.

Although depicted as part of the cross-sectional view presented in FIG. 1, one skilled in the pertinent art would appreciate that the ports 160, 162 (e.g., circular, square or other shapes ports) and their closures 164, 166 could be located in other cross-sections, e.g. in portions of the lid ceiling that do not have nanostructures directly underlying the port, so as to not deter filling or venting liquid metal into or out of the compartment.

FIG. 2 presents a cross-sectional view of another example embodiment of the IC circuit package, including an embodiment of the TIM assembly 110 where the nanostructure seed growth layer 140 is on an interior surface of the lid (e.g., lid surface 134, lid ceiling 115a, FIG. 1A) and the nanostructures 124 are connected to the nanostructure seed growth layer. In some such embodiments, the TIM assembly 110 includes a first metal coupling layer 245 (e.g., similar to the metal coupling layer 145 discussed in the contents of FIG. 1) that holds the nanostructure seed growth layer 140 on the interior surface of the lid, and, a second metal coupling layer 247 that holds the lid on the IC 105 (e.g., coupling the lid walls 115b to the IC 105 to form a liquid-tight seal).

As illustrated in the detail view of FIG. 2A, analogous to that discussed in the context of FIGS. 1 and 1A, the open spaces can include the gaps (e.g., gaps 128a, 128b) between adjacent ones of the nanostructures, gaps 230 between tops 132 of some of the nanostructures (e.g., nanostructure 124b) and an exterior surface 234 of the IC 105, and, the tops 132 of some of the nanostructures (e.g., nanostructures 124a, 124c) can contact the exterior surface 234 of the IC 105.

FIG. 3 presents a cross-sectional view of another example embodiment of the IC circuit package, including another example embodiment of the TIM assembly, where the lid 115 further includes arms 315 sized to extend to and contact a perimeter 317 of a package substrate 150 that the IC package 100 is connected to. Such embodiments can help mitigate warpage of the package substrate 150 and/or distribute mechanical loading on the IC 105 or nanostructure 124 and thereby reduce damage to such structures. Additionally or alternatively, to help mitigate leakage of the liquid metal 126 outside of the IC package 100, the arms 315 contacting the perimeter 317 of the package substrate 150 can form a second compartment 320 with a liquid-tight seal between ends 325 of arms 315 and a surface 330 of the package substrate 150. E.g., in some such embodiments, a coupling layer 335 between the arm's ends 325 and the package substrate's surface 330, can form the liquid-tight seal, similar to that discussed in the context of FIG. 1.

FIG. 4 presents a cross-sectional view of another example embodiment of the IC circuit package, including another example embodiment of the TIM assembly, where a portion of the lid itself can serve as a seed layer (a nanostructure seed growth layer) upon which the nanostructures can be directly grown on, thereby dispensing with the need for a separate nanostructure seed growth layer. That is, for such embodiments, the nanostructures 124 of the TIM assembly 110 are directly connected to an interior surface 415 of the lid ceiling. For instance, there is no intervening material between the nanostructures and the interior surface. For instance, the nanostructure can be formed from material portions of the interior surface (e.g., Cu nanostructure grown from portions of a Cu lid 115).

Another aspect of the disclosure is a method of manufacturing an integrated circuit package.

FIGS. 5A-5E, 6A-6D and FIGS. 7A-7E present cross-sectional views of the IC package 100, such as any of the package embodiments disclosed in the context of FIGS. 1 and 3, at different stages of manufacture where a nanostructure seed growth layer is on the IC 105 and the nanostructures are grown thereon.

FIGS. 8A-8E presents cross-sectional views of an example IC package, such as any of the example embodiments disclosed in the context of FIG. 2, at different stages of manufacture where a nanostructure seed growth layer is on the interior surface of the lid and the nanostructures are grown thereon

FIGS. 9A-9E presents cross-sectional views of an example IC package, such as any of the example embodiments disclosed in the context of FIG. 4, at different stages of manufacture where the interior surface of the lid serves as a nanostructure seed growth layer and the nanostructures are grown directly thereon

With continuing reference to FIGS. 1-9E throughout, any embodiments of the manufacture of the IC packages can include providing an IC 105 and placing a TIM assembly 110 on the IC 105. The TIM assembly includes a lid 115 defining a compartment 120, a mixed-phase material 122 located in the compartment 120, the mixed-phase material including nanostructures 124, and a liquid metal 126 occupying open spaces in the compartment that are not occupied by the nanostructures.

In some embodiments of the method, the placing of the TIM assembly 110 on the IC 105 includes growing the nanostructures 124 on a nanostructure seed growth layer 140 (e.g., FIGS. 5A, 6A, 7A), attaching the nanostructure seed growth layer 140, with the nanostructures 124 thereon, to the IC 105 (e.g., FIG. 5B, 6B, 7A), positioning the lid 115 on the IC 105 (e.g., FIGS. 5C, 6C, 7C), where the compartment 120 holds the nanostructure seed growth layer 140 and nanostructures therein and the lid further includes a fill port 160 and a vent port 162 with conduits 510, 515 respectively, connected thereto (e.g., FIG. 5B, 6B, 7B), and, filling the compartment 120 with the liquid metal 126 by transferring the liquid metal through the conduit 510 connected to the fill port 160 into the compartment 120 (e.g., 5D, 6D, 7D).

In some such embodiments, the positioning of the lid 115 on the IC 105 further includes positioning arms 315 of the lid on a perimeter 317 of the package substrate 150 (e.g., FIG. 5C, 6C, 7C). Some such embodiments further include then connecting the package substrate 150 to a PCB 155 (e.g., FIGS. 5D, 7D). Some such embodiments can further include connecting the IC 105 to a package substrate 150 of the IC package 100 before the placing of the TIM assembly 110 on the IC 105 (e.g., 5A) and then connecting the package substrate 150 to a PCB 155 after the placing of the TIM assembly 110 on the IC 105 (e.g., FIG. 5E). Some such embodiments can further include connecting the IC 105 to a package substrate 150 of the IC package 100 (e.g., FIG. 6B) and then connecting the package substrate 150 to a PCB 155 before the placing of the TIM assembly 110 on the IC 105 (FIG. 6C). In some embodiments, the placing of the TIM assembly 110 on the IC 105 is before connecting the IC 105 to a package substrate 150 of the IC package 100 (e.g., FIG. 7A).

In some embodiments of the method, the placing of the TIM assembly 110 on the IC 105 includes growing the nanostructures 124 on a nanostructure seed growth layer 140 (e.g., FIG. 8A), attaching the nanostructure seed growth layer 140, with the nanostructures 124 thereon, to an interior surface 134 of the lid ceiling 115a (e.g., FIG. 8B), positioning the lid 115 on the IC 105, where the compartment 120 holds the nanostructure seed growth layer 140 and nanostructures therein (e.g., FIG. 8C) and the lid further includes a fill port 160, a vent port 162 with conduits 510, 515 connected thereto (e.g., FIG. 8B), and filling the compartment 120 with the liquid metal by transferring the liquid metal through the conduit 510 connected to the fill port 160 into the compartment 120 (FIG. 8D).

Some such embodiments further include connecting the IC 105 to a package substrate 150 of the IC package 100 (e.g., FIG. 8C) and the positioning of the lid 115 on the IC 105 further includes positioning arms 315 of the lid on a perimeter 317 of the package substrate 150 (FIG. 8C), and then further includes connecting the package substrate 150 to a PCB 155 (e.g., FIG. 8D).

In some embodiments of the method, the placing of the TIM assembly 110 on the IC 105 includes forming the nanostructures 124 directly on an interior surface 134 of the lid ceiling 115a (e.g., FIG. 9A), positioning the lid 115 on the IC 105, where the compartment 120 holds the nanostructure seed growth layer 140 and nanostructures therein where the lid further includes a fill port 160, a vent port 162 with conduits 510, 515 connected thereto (e.g., FIG. 9B), and filling the compartment 120 with the liquid metal by pouring the liquid metal through the conduit 510 connected to the fill port 160 (e.g., FIG. 9C).

Some such embodiments further include connecting the IC 105 to a package substrate 150 of the IC package 100 (e.g., FIG. 9A) and the positioning of the lid 115 on the IC 105 further includes positioning arms 315 of the lid on a perimeter 317 of the package substrate 150 (e.g., FIG. 9B), and then connecting the package substrate 150 to a PCB 155 (e.g., FIG. 9E).

FIGS. 10A-10D present cross-sectional views of an example IC package at different stages of manufacture including aspects of filling a compartment of the TIM assembly with a liquid metal. Embodiments of filling the compartment 120 with the liquid metal 126 includes: placing the IC package 100 in a vacuum chamber 1005 (e.g., FIG. 10B or any embodiments of the IC package 100 depicted in FIGS. 5C, 6C, 7C, 8C, 9C), evacuating air from the vacuum chamber 1005, filling the compartment 120 with the liquid metal 126 by transferring the liquid metal into the compartment 120, through the conduit 510 (e.g., using a dispenser 1010} connected to the fill port 160 (e.g., FIG. 10C), removing the IC package 100 from the vacuum chamber 1005 (e.g., FIG. 10D) removing the conduit 510 from the fill port 160), and sealing the fill port 160 and the vent port 162 with closures, e.g., fill closure 164 and vent closure 166, respectively (e.g., FIGS. 5E, 6D, 7E, 8E, 9E, 10D).

Any such embodiments can further include, while filling the compartment 120 with the liquid metal, transferring portions of the liquid metal leaving the compartment 120 through the conduit 515 connected to the vent port 162, e.g., to avoid spilling excess liquid metal on the IC 105, package substrate 150 or PCB 155 or any components thereon.

One skilled in the pertinent arts would be familiar with procedures to grow nanostructures on a surface (e.g., a nanostructure seed growth layer surface or interior lid surface). As a non-limiting example, an electrically conductive (e.g., Cu) nanostructure seed growth layer surface or interior lid surface or exposed portion thereof can be a cathode in an electrodeposition process, where a porous membrane is attached to the surface and then all or a portion of the nanostructure seed growth layer or lid is placed in a electroplating solution (e.g., a CuSO₄ electroplating solution) and electrically current applied to electroplate nanostructures in the pores of the membrane with an anode (e.g., an oxygen-free high thermal conductivity copper anode and pulsed direct current) until the nanostructures fill the pores. Or, nanostructures of carbon nanotubes (e.g., multiwalled carbon nanotubes) grown on a nanostructure seed growth layer of silicon previously coated with Al₂O₃ and Fe deposited by e-beam evaporation.

Another embodiment of the disclosure is computer having one or more circuits that include the IC package as disclosed herein. FIG. 11 presents a block diagram of a computer including one or more embodiments of the IC package 100. The IC package 100 include a computer 1100 having one or more circuits 1110 that include any embodiments of the IC package 100, including any embodiments of the TIM assembly 110, such as disclosed in the context of FIGS. 1-4, and/or, manufactured such as disclosed in the context of FIGS. 5A-10D.

Those skilled in the art to which this application relates will appreciate that other and further additions, deletions, substitutions and modifications may be made to the described embodiments.

What is claimed is:

1. An IC package, comprising:
an IC; and
a thermal interface material (TIM) assembly located on the IC, the TIM assembly including:
a lid defining a compartment,
a mixed-phase material located in the compartment, the mixed-phase material including nanostructures and a liquid metal occupying open spaces in the compartment that are not occupied by the nanostructures.

2. The IC package of claim 1, wherein the open spaces include gaps between adjacent ones of the nanostructures.

3. The IC package of claim 1, wherein the open spaces include gaps between tops of some of the nanostructures and an interior surface of the lid.

4. The IC package of claim 3, wherein tops of some of the nanostructures contact the interior surface of the lid.

5. The IC package of claim 1, wherein the TIM assembly further includes a nanostructure seed growth layer, wherein the nanostructures are connected to the nanostructure seed growth layer and the nanostructure seed growth layer is on the integrated circuit.

6. The IC package of claim 5, wherein the TIM assembly further includes a metal coupling layer that holds the lid and the nanostructure seed growth layer on the IC.

7. The IC package of claim 6, wherein the metal coupling layer forms a liquid-tight seal between the lid and the IC.

8. The IC package of claim 1, wherein the IC is connected to a package substrate of the IC package and the package substrate is connected to a printed circuit board of the IC package.

9. The IC package of claim 1, wherein the lid further includes ports with closures to seal the liquid metal in the compartment.

10. The IC package of claim 1, wherein the TIM assembly includes a nanostructure seed growth layer on an interior surface of the lid and the nanostructures are connected to the nanostructure seed growth layer.

11. The IC package of claim 1, wherein the TIM assembly includes first a metal coupling layer that holds the nanostructure seed growth layer on the interior surface of the lid and a second metal coupling layer that holds the lid on the IC.

12. The IC package of claim 1, wherein the lid further includes arms sized to extend to and contact a perimeter of a package substrate that the IC package is connected to.

13. The IC package of claim 9, wherein the arms contacting the perimeter of the package substrate forms a second compartment with a liquid-tight seal between ends of arms and a surface of the package substrate.

14. The IC package of claim 1, wherein the nanostructures are directly connected to an interior surface of the lid ceiling.

15. A method of manufacturing an IC package, comprising:
providing an IC; and
placing a thermal interface material (TIM) assembly on the IC, the TIM assembly including:
a lid defining a compartment, and
a mixed-phase material located in the compartment, the mixed-phase material including nanostructures, and
a liquid metal occupying open spaces in the compartment that are not occupied by the nanostructures.

16. The method of claim 15, wherein placing the TIM assembly on the IC, includes:
growing the nanostructures on a nanostructure seed growth layer,
attaching the nanostructure seed growth layer, with the nanostructures thereon, to the IC,
positioning the lid on the IC 105, wherein the compartment holds the nanostructure seed growth layer and nanostructures therein wherein the lid further includes a fill port, a vent port with conduits connected thereto, and
filling the compartment with the liquid metal by transferring the liquid metal through the conduit connected to the fill port into the compartment.

17. The method of claim 15, wherein the placing of the TIM assembly on the IC includes:
growing the nanostructures on a nanostructure seed growth layer,
attaching the nanostructure seed growth layer, with the nanostructures thereon, to an interior surface of the lid ceiling,
positioning the lid on the IC, wherein the compartment holds the nanostructure seed growth layer and nanostructures therein wherein the lid further includes a fill port, a vent port with conduits connected thereto, and
filling the compartment with the liquid metal by transferring the liquid metal through the conduit connected to the fill port into the compartment.

18. The method of claim 15, wherein the placing of the TIM assembly on the IC includes:
forming the nanostructures directly on an interior surface of the lid ceiling,
positioning the lid on the IC, wherein the compartment holds the nanostructure seed growth layer and nanostructures therein wherein the lid further includes a fill port, a vent port with conduits connected thereto, and
filling the compartment with the liquid metal by pouring the liquid metal through the conduit connected to the fill port.

19. The method of claim 15, wherein filling the compartment with the liquid metal includes:
placing the IC package in a vacuum chamber,
evacuating air from the vacuum chamber,
filling the compartment with the liquid metal by transferring the liquid metal into the compartment through the conduit connected to the fill port,
removing the IC package from the vacuum chamber,
removing the conduit from the fill port, and
scaling the fill port and the vent port with closures.

20. A computer having one or more circuits that include the IC package of claim 1.
